(19) United States
(12) Patent Application Publication
(10) Pub. No.: US 2019/0019829 A1
(43) Pub. Date: Jan. 17, 2019

(54) IMAGE SENSOR

(71) Applicant: National ICT Australia Limited, Eveleigh, New South Wales (AU)

(72) Inventor: Antonio Robles-Kelly, Eveleigh, New South Wales (AU)

(21) Appl. No.: 16/070,051

(22) PCT Filed: Jan. 12, 2017
(86) PCT No.: PCT/AU2017/050020

§ 371 Date: Jul. 13, 2018

(30) Foreign Application Priority Data
Jan. 13, 2016 (AU) 2016900098

(51) Int. Cl. H01L 27/146; H04N 5/225; H04N 5/232

(52) U.S. Cl. CPC H01L 27/14621; H01L 27/14627; G06T 7/593; H04N 5/2254; H04N 5/23229; H01L 27/14645

(57) ABSTRACT

This disclosure relates to a sensor for acquiring image data. Multiple imaging elements generate an intensity signal indicative of an amount of light incident on that imaging element. There is also an array of multiple lenses, each of the multiple lenses being associated with more than one of the multiple imaging elements and each of the multiple lenses of the array being associated with exactly one filter such that the intensity signals generated by the more than one of the multiple imaging elements associated with that lens represent a part of the image data. As a result, the alignment between lenses and filters is simplified because each lens and filter combination is associated with multiple imaging elements.

### TECHNICAL FIELD

This disclosure relates to sensors and methods for acquiring image data.

### BACKGROUND ART

Most cameras provide images in multiple different colours, such as red, green and blue (RGB). Each colour relates to a particular frequency band in the visible spectrum from about 400 nm to about 700 nm and an image sensor detects the intensity of light at these frequency bands. More particularly, the image sensor comprises an array of imaging elements and each imaging element is designated for one of the colours red, green and blue by placing a corresponding filter in front of that imaging element.

FIG. 1 illustrates a prior art image sensor 100 comprising an detector layer 102, a lens layer 104 and a filter layer 106. Each filter of filter layer 106 is aligned with one lens of lens layer 104 and one imaging element of detector layer 102. The filters of filter layer 106 for different colours are arranged in a mosaic as illustrated by the different shading where each shading represents one of the colours red, green and blue.

FIG. 2 illustrates the light path for a single imaging element in more detail. FIG. 2 comprises a single lens 202 from lens layer 104, a single filter 204 from filter layer 106 and a single imaging element 206 from detector layer 102.

Imaging element 206 comprises a photo diode 208, a column selection transistor 210, an amplifier transistor 212 and a row activation transistor 214. The current through photo diode 208 depends on the amount of light that reaches the photo diode 208. Amplifier transistor 212 amplifies this current and an image processor (not shown) is connected to the amplifier output via row and column lines to measure this amplified current and to A/D convert the amplified voltage into a digital intensity signal representing the intensity of light reaching the photodiode. The digital intensity signal is then referred to as a colour value for one pixel. A pixel is defined as a group of imaging elements, such as imaging element 206, such that each colour is represented at least once. The individual imaging elements are also referred to as sub-pixels. In many RGB sensors, there are two green, one red and one blue sub-pixels per pixel to make up one 2×2 square of imaging elements as indicated by the thick rectangle 108 in FIG. 1. Combining more than three different colour filters and more sub-pixels into one pixel allows hyperspectral imaging. For example, a 5×5 mosaic can capture up to 25 bands in the visible or visible and near-infrared range.

As can be seen in FIG. 2, the photodiode 208, which is the element receptive to incident light, does not cover the entire surface of the imaging element. This would reduce the sensitivity of the sensor as the light that falls on transistors 210, 212 and 214 would be lost instead of contributing to the signal. This loss of light reduces the signal to noise ratio. As a solution, lens 202 is placed above the imaging element and concentrates the light onto photodiode 208 to increase the signal to noise ratio.

A problem with the arrangement shown in FIGS. 1 and 2 is that a small misalignment of the lenses 106, filters 104 and imaging elements 102 relative to each other lead to blurring due to overlap between neighbouring sub-pixels. As a result, the manufacturing process is complex and expensive. Despite all the efforts during process optimisation, the alignment is often inaccurate.

Any discussion of documents, acts, materials, devices, articles or the like which has been included in the present specification is not to be taken as an admission that any or all of these matters form part of the prior art base or were common general knowledge in the field relevant to the present disclosure as it existed before the priority date of each claim of this application.

Throughout this specification the word “comprise”, or variations such as “comprises” or “comprising”, will be understood to imply the inclusion of a stated element, integer or step, or group of elements, integers or steps, but not the exclusion of any other element, integer or step, or group of elements, integers or steps.

### DISCLOSURE OF INVENTION

A sensor for acquiring image data comprises:
multiple imaging elements, each of the multiple imaging elements being configured to generate an intensity signal indicative of an amount of light incident on that imaging element; and
an array of multiple lenses, each of the multiple lenses being associated with more than one of the multiple imaging elements and each of the multiple lenses of the array being associated with exactly one filter such that the intensity signals generated by the more than one of the multiple imaging elements associated with that lens represent a part of the image data.

It is an advantage that the alignment between lenses and filters is simplified because each lens and filter combination is associated with multiple imaging elements.

The sensor may further comprise a focusing element in front of the array of multiple lenses.

The focusing element may be configured such that when the sensor captures an image of a scene each of the multiple lenses projects the scene onto the multiple imaging elements associated with that lens.

The sensor may further comprise a processor to determine multispectral image data based on the intensity signals, the multispectral image data comprising for each of multiple pixels of an output image wavelength indexed image data.

The sensor may further comprise a processor to determine depth data indicative of a distance of an object from the sensor based on the intensity signals.

The more than one imaging elements associated with each of the multiple lenses may create an image associated with that lens and the processor may be configured to determine the depth data based on spatial disparities between images associated with different lenses.

All the intensity signals representing a part of the hyperspectral image data may be created by exactly one filter and exactly one of the multiple lenses.

The exactly one filter associated with each of the multiple lenses of the array may be a single integrated filter for all of the multiple lenses and the filter has a response that is variable across the filter.

The filter may be a colour filter and the part of the image data may be a spectral band of hyperspectral image data.

The filter may be a polariser and the part of the image data may be a part that is polarised in a direction of the polariser.

A method for acquiring image data comprises:
directing light reflected from a scene onto an array of multiple lenses;
directing light transmitted through each of the multiple lenses through exactly one filter;
p and detecting the light transmitted through each of the multiple lenses and the exactly one filter with more than one of multiple imaging elements.

A method for determining image data comprises:
receiving intensity signals from multiple sets of imaging elements, each set of imaging elements being associated with exactly one of multiple lenses and exactly one filter to represent a part of the image data; and
determining based on the intensity signals the image data.

Software that, when installed on a computer, causes the computer to perform the above method.

A computer system for determining image data comprises:
an input port to receive intensity signals from multiple sets of imaging elements, each set of imaging elements being associated with exactly one of multiple lenses and exactly one filter to represent a spectral band of the image data; and
a processor to determine based on the intensity signals the image data.

Optional features described of any aspect of method, computer readable medium or computer system, where appropriate, similarly apply to the other aspects also described here.

### BRIEF DESCRIPTION OF DRAWINGS

FIG. 1 illustrates a prior art image sensor.

FIG. 2 illustrates the light path for a single imaging element in more detail.

An example will now be described with reference to:

FIG. 3 illustrates a sensor for acquiring hyperspectral image data using colour filters.

FIG. 4 illustrates another example assembly comprising focusing optics.

FIG. 5 illustrates a paraxial optical diagram.

FIG. 6a illustrates a single lenslet configuration used for simulation.

FIG. 6b illustrates a resulting wavefront.

FIG. 6c illustrates an interferogram for the model in FIG. 6a.

FIG. 7 illustrates a paraxial optical diagram showing the displacement of a scene point with respect to two lenslets.

FIG. 8 is a photograph of an example system based on a Flea 1 camera.

FIG. 9a illustrates an image delivered by the example system based on the Flea 1 camera.

FIG. 9b illustrates an image obtained using the same configuration and a Flea 2 camera.

FIG. 10a illustrates an example scenario captured by the sensor of FIG. 3.

FIG. 10b illustrates an exaggerated change of relative positions of objects in the image due to their different depth.

FIG. 11 illustrates a computer system for determining hyperspectral image data.

FIG. 12 illustrates a data structure 1200 for the output multispectral image data.

FIG. 13 illustrates the depth layer in the example scene of FIG. 10a as a greyscale image.

FIG. 14 illustrates a sensor for acquiring hyperspectral image data using polarisers.

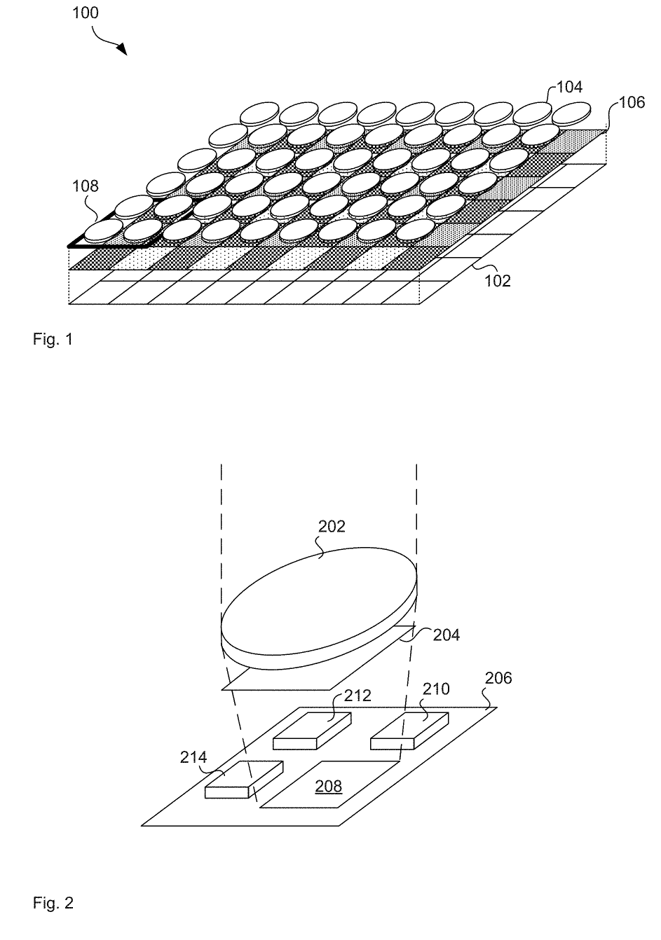

### MODES FOR CARRYING OUT THE INVENTION

There is disclosed herein a camera concept, which not only avoids this need for alignment but also delivers a depth estimate together with a hyperspectral image. Hyperspectral in this disclosure means more than three bands, that is, more than the three bands of red, green and blue that can be found in most cameras.

It is worth noting that the system presented here differs from other approaches in a number of ways. For example, the filters are not to be on the sensor but rather on the microlens array. This alleviates the alignment problem of the other cameras. Moreover, the configuration presented here can be constructed using any small form-factor sensor and does not require complex foundry or on-chip filter arrays.

Moreover, the system presented here is a low-cost, compact alternative to current hyperpsectral imagers, which are often expensive and cumbersome to operate. This setting can also deliver the scene depth and has no major operating restrictions, as it has a small form factor and its not expected to be limited to structured light or indoor settings. These are major advantages over existing systems.

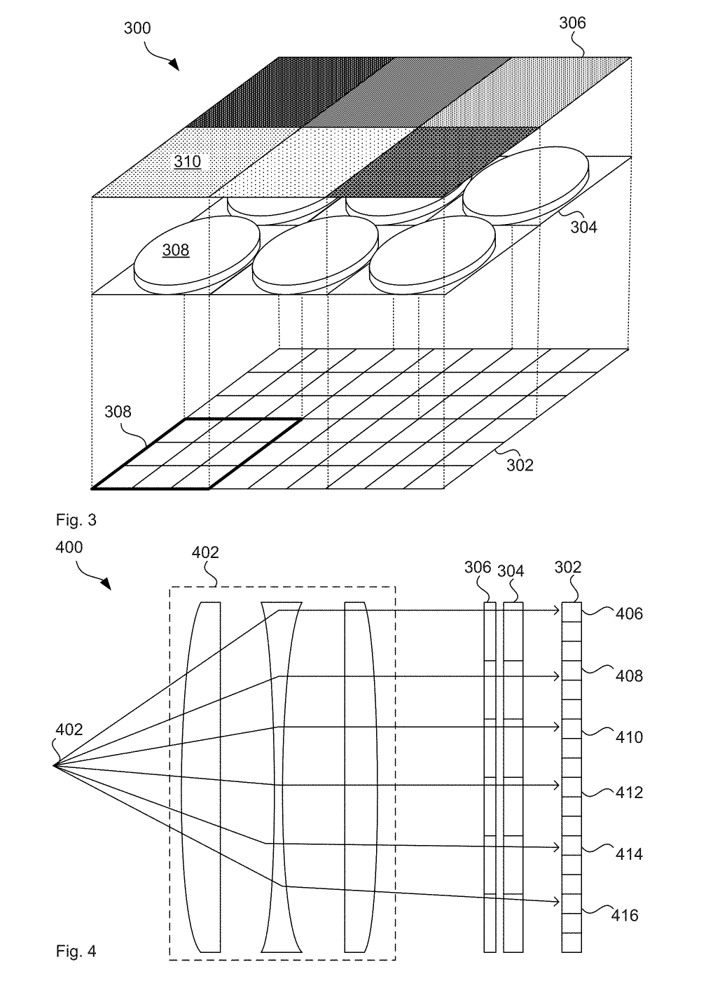

FIG. 3 illustrates such a sensor 300 for acquiring hyperspectral image data using colour filters. Sensor 300 comprises multiple imaging elements in a detector layer 302. Each of the multiple imaging elements 302 is configured to generate an intensity signal indicative of an amount of light incident on that imaging element as described above. That is, the intensity signal reflects the intensity of light that is incident on the photodiode 208 of the imaging element 206. In one example, the imaging elements 302 are CMOS imaging elements integrated into a silicon chip, such as CMOSIS CMV4000. While the examples herein are based on CMOS technology, other technologies, such as CCD may equally be used.

Sensor 300 further comprises an array 304 of multiple lenses and a filter layer 306. An array is a two-dimensional structure that may follow a rectangular or quadratic grid pattern or other layouts, such as a hexagonal layout. Each of the multiple lenses is associated with more than one of the multiple imaging elements 302. In this example, each lens of array 304 is associated with nine (3×3) imaging elements as indicated by thick rectangle 308.

Further, each of the multiple lenses of the array 304 is associated with exactly one colour filter of filter layer 306 such that the intensity signals generated by the more than one of the multiple imaging elements associated with that lens represent a spectral band of the hyperspectral image data. Being associated in this context means that light that passes through the lens also passes through the filter associated with that lens and is then incident on the imaging element also associated with that lens.

In the example of FIG. 3, example lens 308 is associated with the nine imaging elements indicated at 308 and example filter 310 and no other filter. While FIG. 3 shows six spectral bands only, this pattern with corresponding lenses is repeated to cover the entire image sensor. In other examples, instead of six spectral bands, there may be 5×5 spectral bands. In further examples, the mosaic pattern is not repeated but instead, each filter is sized such that all filters together cover the entire chip area. For example, the chip may have a resolution of 2048×2048 imaging elements in detector layer 302 and 8×8 different colour filters are placed above the chip with 8×8 corresponding lenses resulting in 64 different bands. Each band is then captured by 256 imaging elements, which means each lens is associated with 256 (16×16) imaging elements.

In another example, the colour filters of layer 306 are realised as an integrate filter layer for all of the multiple lenses of layer 304. The integrated filter may have a colour response that is variable across the colour filter, such as a gradient in the colour wavelengths from near infrared at one end of the filter to ultra-violet at the opposite end. Such a variable filter also has a unique response at any point. In one example, the integrated filter is a spatially variable response coating, such as provided by Research Electro-Optics, Inc. Boulder, Colo. (REO).

FIG. 4 illustrates another example assembly 400 comprising focusing optics 402 in addition to the elements described above, that is, a set of filters 306 on a microlens array 304 and an image sensor 302. The focusing optics in combination with the microlens array produce a “replicated” view which is tiled on the image sensor 302. In other words the focusing element is configured such that when the sensor captures an image of a scene each of the multiple lenses projects the entire scene onto the multiple imaging elements (“tile”) associated with that lens.

Since the filters 306 are to be on the microlens array 304, each of these replicated views is wavelength resolved. These replicas are not identical, but rather shifted with respect to each other. The shift in the views is such that two pixels corresponding to the same image feature are expected to show paraxial shifts.

For example, the light beams from single point 402 all reach imaging elements 406, 408, 410, 412 and 414, which results in five different views of the same point 402 for five different wavelengths. It is noted that the optical paths illustrated by arrows in FIG. 4 are simplified for illustrative purposes. More accurate paths are provided further below.

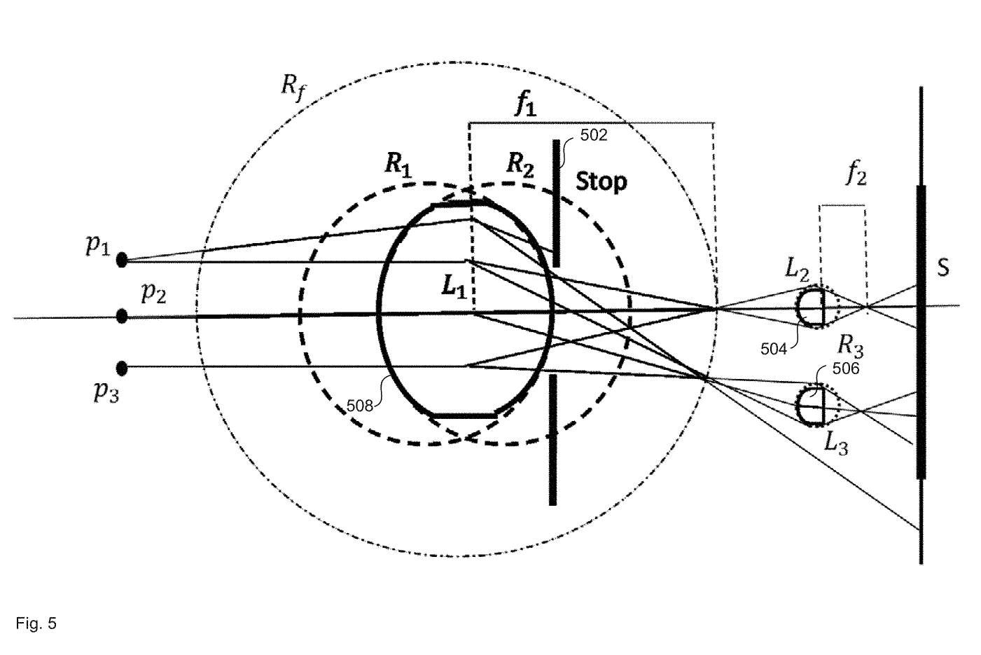

FIG. 5 illustrates a paraxial optical diagram for the proposed system, where each of the microcams deliver one of the wavelength-resolved channels of the image. FIG. 5 shows a stop 502 included in the optics and provide an explanation considering only a first lenslet 504 and a second lenslet 506 without any loss of generality for the sake of clarity.

The focal length equations of the system are those corresponding to a convex and a plano-convex lenses in FIG. 5. These are as follows:

$$\begin{matrix}\frac{1}{{f}_{1}} = ( η - 1 ) ( \frac{1}{{R}_{1}} - \frac{1}{{R}_{2}} + \frac{( η - 1 ) d}{η {R}_{1} {R}_{2}} ) & ( 1 ) \\ \frac{1}{{f}_{2}} = \frac{( η - 1 )}{{R}_{3}} & ( 2 )\end{matrix}$$

where Equation 1 corresponds to the lens L₁ 508 and Equation 2 accounts for either of the two lenslets L₂ 504 or L₃ 506, respectively. The variables in the equations above correspond to the annotations in FIG. 5 and denote the thickness of the lens as d and its index of refraction as η. Moreover, by setting η=1.46 (this value is well within the National Physics Laboratory standard for fused silica lens arrays at 580 nm) and f₁=16 mm, it is possible to model the camera optics using WinLens.

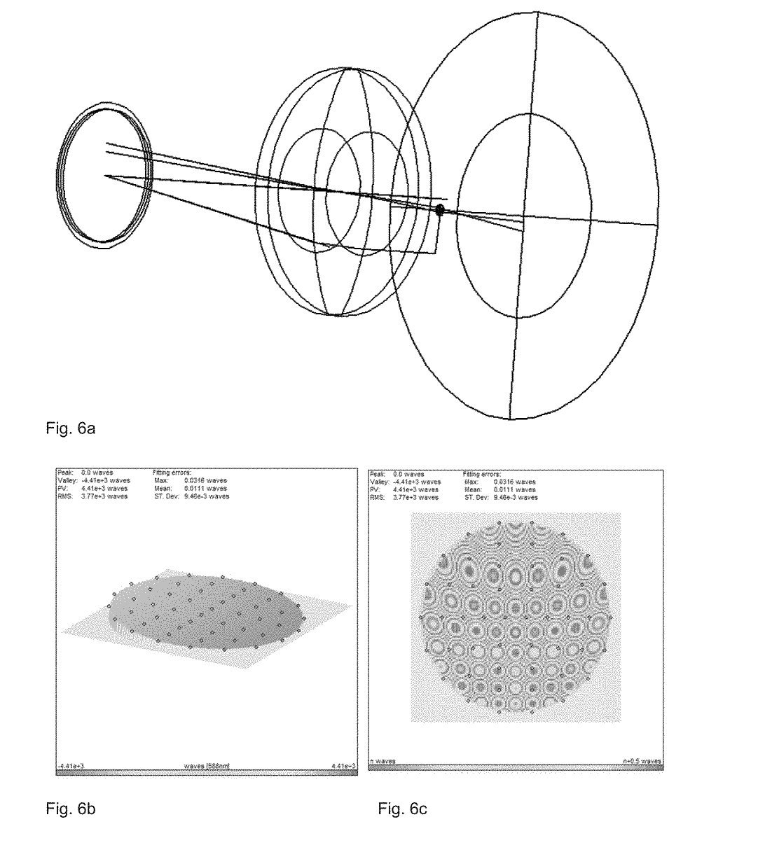

The wavefront simulation for a single lenslet, is shown in FIGS. 6a, 6b and 6c. FIG. 6a illustrates a single lenslet configuration used for simulation. FIG. 6b illustrates the resulting wavefront while FIG. 6c illustrates an interferogram for the model in FIG. 6a.

Note that the wavefront in FIG. 6b is “tilted” with respect to the chief ray of the system passing through the axis of the lens L₁ since the focal length of the lens will determine the radius R_{f}, as shown in FIG. 5. The tilt angle will hence be a function of the distance between the two focal elements, the displacement of the lenslet with respect to the chief ray and the focal length f₁. This is consistent with the interferogram and the wavefront shown in the figure where the interference patterns describe Sinc functions that are “projected” onto a titled propagation plane.

In another example, the proposed system also acquires depth information. Note that, as the lenslets shift off-centre, a point in the scene also shifts over the respective tiled views on the image sensor.

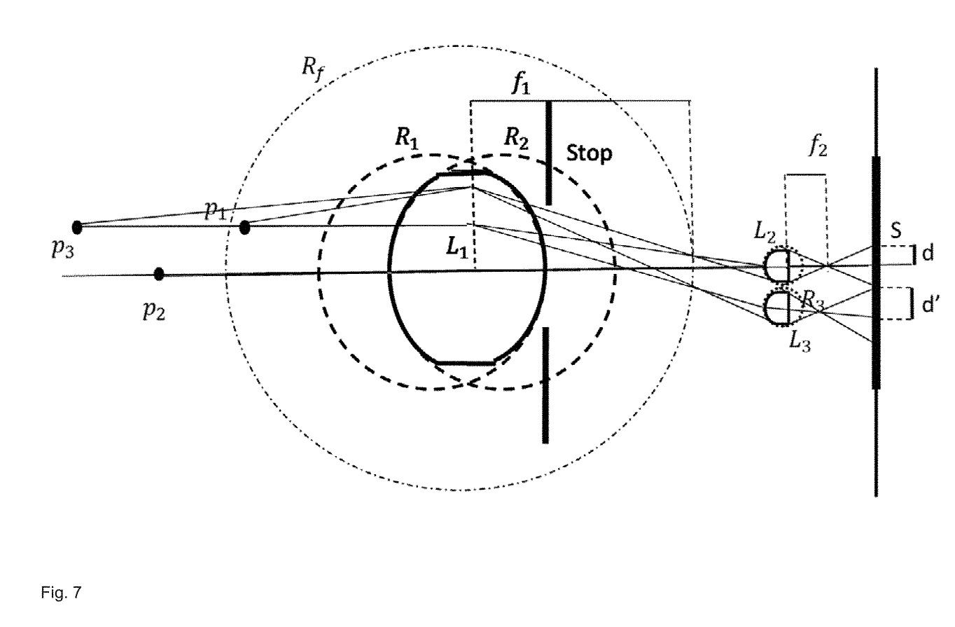

FIG. 7 illustrates a paraxial optical diagram showing the displacement of a scene point with respect to two lenslets in the array. FIG. 7 is a redrawn version of the paraxial optics in FIG. 5 so as to show the increment in d′. Note that the system actually exhibits an inverted parallax whereby the further the object is, the displacement is expected to increase on the image plane. This opens up the possibility of obtaining both, a depth estimate as well as the hyperspectral or multispectral image cube.

In one example, the sensor comprises two different cameras. The first of these may be a Flea 1 firewire camera. The second one may be a Flea 2. Both are manufactured by Point Gray.

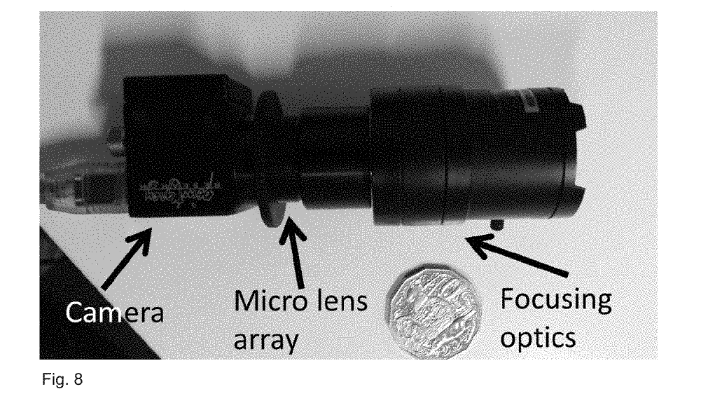

FIG. 8 is a photograph of an example system based on a Flea 1 camera. The lens attached to the relay optics, i.e. the microlens array, is a Computar f/2.8 12 mm varifocal with a manual iris ⅓″ and a CS 1:1.3 amount. The microlens array is a 10×10 mm sheet with a lenslet pitch of 1015 μm. These dimensions are consistent with the report and the industry standard pitch in arrays stocked by SÜSS MicroOptics, the size of the lenslet and pitch may depend on several factors, such as the number of views desired, the focal length of the focusing optics, i.e. main lens, and size of the sensor.

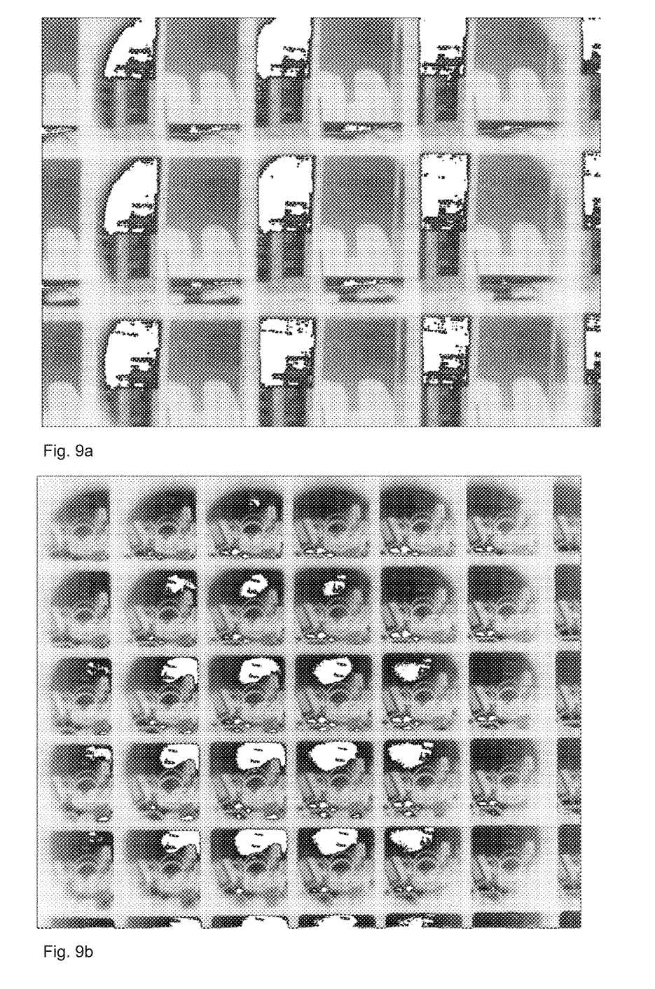

FIG. 9a illustrates an image delivered by the example system based on the Flea 1. FIG. 9b illustrates an image obtained using the same configuration and a Flea 2 camera. Note that these are not hyperspectral images but rather the trichromatic views as captured by the Flea cameras. The idea is that each of these would become a wavelength resolved channel in the image as the filter becomes attached to the lenslet.

Note that, in FIGS. 9a and 9b, the image features are shifted from view to view in a manner consistent with the parallax effect induced by the microlens array. This is more noticeable in FIG. 9a, where the chairs, the board and the monitor all shift between views at different rates. It is also noticeable the effect of the resolution and size of the sensor on the output image.

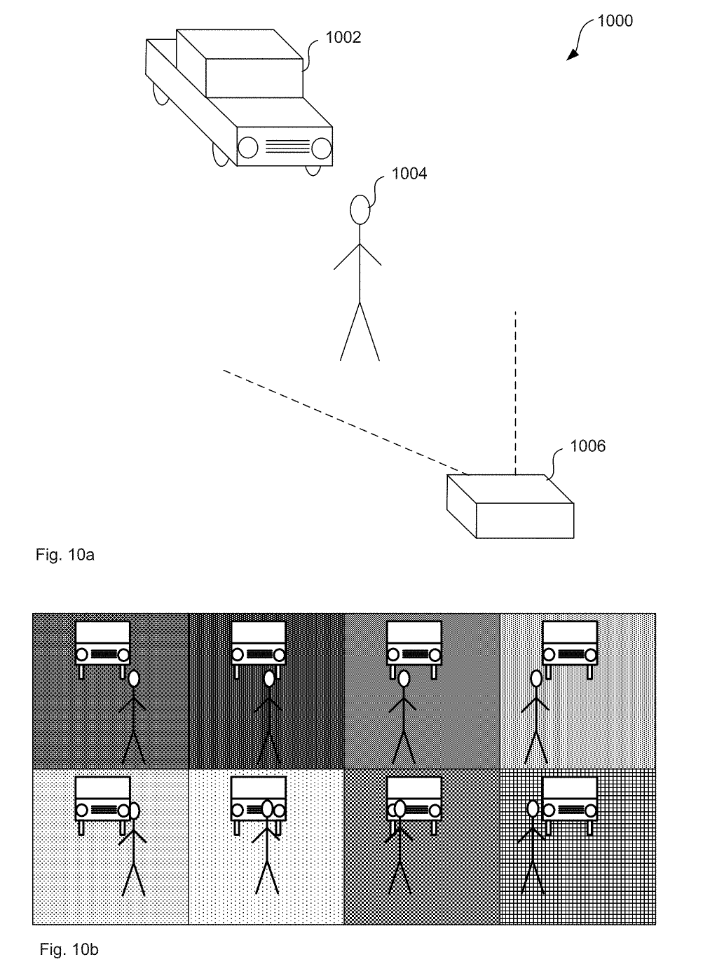

FIG. 10a illustrates an example scenario 1000 comprising a car 1002 and a pedestrian 1004 captured by a camera 1006 is described with reference to FIG. 3. FIG. 10b schematically illustrates the image as captured by the image sensor. The image comprises eight tiles where the shading of each tile indicates the different wavelength selected by the corresponding filter. FIG. 10b illustrates in an exaggerated way how the position of the pedestrian 1004 relative to the car 1002 changes between the different image tiles since the scene 1000 is viewed from a slightly different angle. It is noted that all the image tiles shown in FIG. 10b are acquired by detector layer 302 at the same time and adjacent to each other on the detector layer 302.

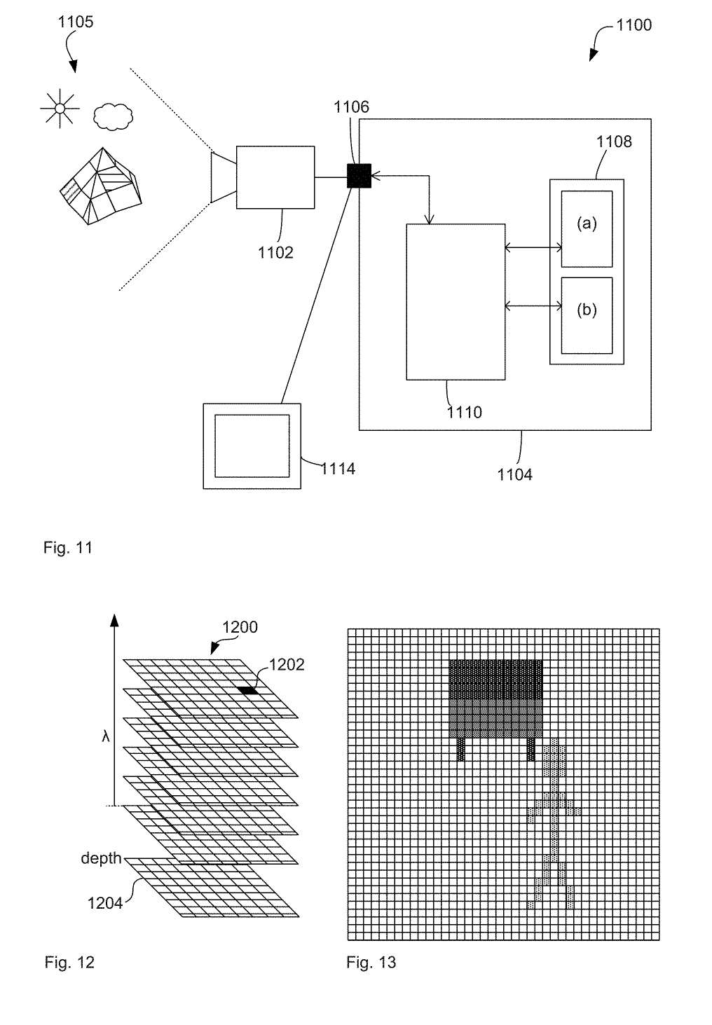

FIG. 11 illustrates a computer system 1100 for determining hyperspectral image data. Computer system 1100 comprises a sensor 1102 and a computer 1104. In this example the sensor 1102 is the hyperspectral or multispectral sensor described above directed at a scene 1105.

In one example, the computer system 1100 is integrated into a handheld device such as a consumer or surveillance camera and the scene 1105 may be any scene on the earth, such as a tourist attraction or a person, or a remote surveillance scenario.

The computer 1104 receives intensity signals from the sensor 1102 via a data port 1106 and processor 1110 stores the signals in data memory 1108(b). The processor 1110 uses software stored in program memory 1108(a) to perform the method receiving intensity signals and determining hyperspectral image data based on the received intensity signals. The program memory 1108(b) is a non-transitory computer readable medium, such as a hard drive, a solid state disk or CD-ROM.

Software stored on program memory 1108(a) may cause processor 1110 to generate a user interface that can be presented to the user on a monitor 1112. The user interface is able to accept input from the user (i.e. touch screen). The monitor 1112 provides the user input to the input/out port 1106 in the form of interrupt and data signals. The sensor data and the multispectral or hyperspectral image data may be stored in memory 1108(b) by the processor 1110. In this example the memory 1108(b) is local to the computer 1104, but alternatively could be remote to the computer 1104.

The processor 1110 may receive data, such as sensor signals, from data memory 1108(b) as well as from the communications port 1106. In one example, the processor 1110 receives sensor signals from the sensor 1102 via communications port 1106, such as by using a Wi-Fi network according to IEEE 802.11. The Wi-Fi network may be a decentralised ad-hoc network, such that no dedicated management infrastructure, such as a router, is required or a centralised network with a router or access point managing the network.

In one example, the processor 1110 receives and processes the sensor data in real time. This means that the processor 1110 determines multispectral or hyperspectral image data every time the image data is received from sensor 1102 and completes this calculation before the sensor 1102 sends the next sensor data update. This may be useful in a video application with a framerate of 60 fps.

Although communications port 1106 is shown as single entity, it is to be understood that any kind of data port may be used to receive data, such as a network connection, a memory interface, a pin of the chip package of processor 1110, or logical ports, such as IP sockets or parameters of functions stored on program memory 1108(a) and executed by processor 1110. These parameters may be stored on data memory 1108(b) and may be handled by-value or by-reference, that is, as a pointer, in the source code.

The processor 1110 may receive data through all these interfaces, which includes memory access of volatile memory, such as cache or RAM, or non-volatile memory, such as an optical disk drive, hard disk drive, storage server or cloud storage. The computer system 1104 may further be implemented within a cloud computing environment, such as a managed group of interconnected servers hosting a dynamic number of virtual machines.

It is to be understood that any receiving step may be preceded by the processor 1110 determining or computing the data that is later received. For example, the processor 1110 determines the sensor data, such as by filtering the raw data from sensor 1102, and stores the filtered sensor data in data memory 1108(b), such as RAM or a processor register. The processor 1110 then requests the data from the data memory 1108(b), such as by providing a read signal together with a memory address. The data memory 1108(b) provides the data as a voltage signal on a physical bit line and the processor 1110 receives the sensor data via a memory interface.

Processor 1110 receives image sensor signals, which relates to the raw data from the sensor 1102. After receiving the image sensor signals, processor 1110 may perform different image processing and computer vision techniques to recover the scene depth and reconstruct the hyperspectral image cube. That is, processor 1110 performs these techniques to determine for each pixel location multiple wavelength indexed image values. In addition to these image values that make up the hyperspectral image cube, processor 1110 may also determine for each pixel a distance value indicative of the distance of the object from the camera 1106. In other words, the distance values of all pixels may be seen as a greyscale depth map where white indicates very near objects and black indicates very far objects.

The image processing techniques may comprise deblurring methods where the mask is adapted from tile to tile to image enhancement through the use of the centre tiles (these do not suffer from serious blur) for methods such as gradient transfer as described in P. Perez, M. Gangnet, and A. Blake. Poisson image editing. ACM Trans. Graph., 22(3):313-318, 2003, which is incorporated herein by reference. Processor 1110 may also perform super-resolution techniques or determine depth estimates to improve photometric parameter recovery methods such as that in C. P. Huynh and A. Robles-Kelly. Simultaneous photometric invariance and shape recovery. In International Conference on Computer Vision, 2009, which is incorporated herein by reference. Thirdly, as said earlier, the proposed configuration is a cheap alternative to other hyperspectral cameras. The Flea cameras may have a resolution between 0.7 and 5 MP. These can be substituted with cameras with a much greater resolution such as the Basler Ace USB 3.0 camera with a 15 MP resolution.

In one example, processor 1110 may apply machine learning, data driven approaches to determine or learn parameters of known transformation. That is, processor 1110 solves equations on a large amount of data, that is, the data from the image sensor representing the parallax shift of the known object. In other words, the disparities between the image in tiles of different wavelengths relate to respective equations and processor 1110 solves these equation or optimises error functions to determine the best fit of the camera parameters to the observed data.

In particular, it may be difficult to manufacture a particular focal length for lenslets. So instead, processor 1110 may learn the focal length and thereby account for manufacturing variation for each individual image sensor. The result may include inverted depth, pitch, thickness, index of refraction and based on f1 processor determines f2. With these camera parameters processor can apply algorithms of inverted parallax to take advantage of the depth dependent disparity between image tiles. That is, processor 1110 uses the difference in two difference images and recovers the depth out of the disparity based on triangulation.

Processor 1110 may further perform a stereo vision method as described in L. Boyer, A. C. Kak, Structural stereopsis for 3-D vision, IEEE Trans. Pattern Anal. Machine Intell. 10 (1988), 144-16, which is incorporated herein by reference. This is applicable since each of the imaging elements acquires a displaced image whose parameters are determined by the lens equation and the position of the lenses with respect to the camera plane. Thus, each of the acquired scenes is one of the displaced views that processor 1110 then uses in a manner akin to stereo vision to recover depth.

FIG. 12 illustrates a data structure 1200 for the output multispectral image data. The data structure 1200 comprises layers, one for each wavelength. Each layer comprises input values that are representative of the intensity associated with a wavelength index. One example pixel 1202 is highlighted. The intensity values of pixel 1202 associated with different wavelengths, that is the radiance input values from lower layers at the same location as pixel 1202, represent a radiance spectrum also referred to as the image spectrum. This image spectrum may be a mixture of multiple illumination spectra and the reflectance spectra of different materials present in the part of the scene that is covered by pixel 1202. Data structure 1200 further comprises a depth layer 1204. The values for each pixel in the depth layer 1204 represent the distance of the camera from the object in the scene that is captured in that pixel.

FIG. 13 illustrates the depth layer 1204 in the example scene of FIG. 10a as a greyscale image. It can be seen that the pedestrian 1004 in the foreground is displayed in a lighter shade of grey as the pedestrian 1004 is closer to the camera 1006. The front of the car 1002 is displayed in a darker shade to illustrate a greater distance from camera 1006. The windscreen and tires of car 1002 are displayed in a yet darker shade to illustrate a yet further distance from camera 1006.

The spectra for each pixel may be stored in a compact form as described in PCT/AU2009/000793.

Processor 1110 may recover the illumination spectrum from the hyperspectral image data as described in PCT/AU2010/001000, which is incorporated herein by reference, or may determine colour values as described in PCT/AU2012/001352, which is incorporated herein by reference, or cluster the image data as described in PCT/AU2014/000491, which is incorporated herein by reference. Processor 1110 may also process the hyperspectral image data as described in PCT/AU2015/050052, which is incorporated herein by reference.

Processor 1110 may decompose the image data into material spectra is described in U.S. Pat. No. 8,670,620, which is incorporated herein by reference.

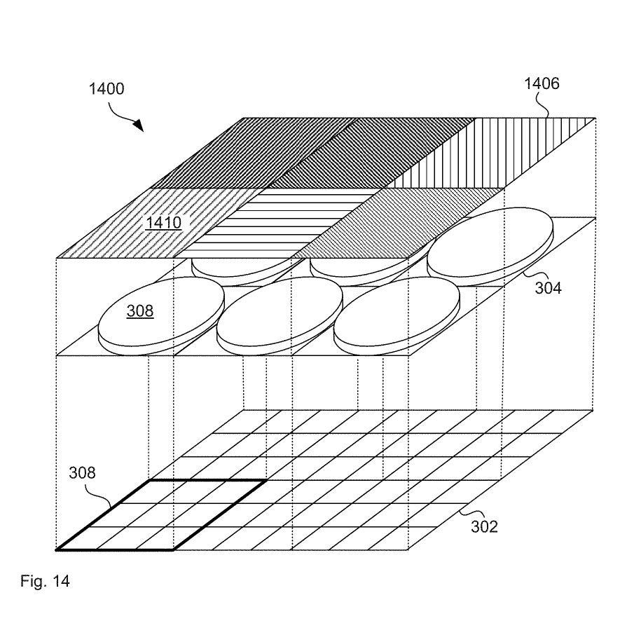

FIG. 14 illustrates a sensor 1400 for acquiring image data using polarisers. Polarisers may also be referred to as filters since they essentially filter light with a predefined polarisation angles. The layer structure is similar to the structure in FIG. 3 with the main difference of layer 1406, which now comprises polarisers, such as example polariser 1410. The direction of the hatching in layer 1406 visually indicates the different polarisation angle of each filter in layer 1406. In one example, the angle is distributed evenly across 0-180 degrees, such as 0, 30, 60, 90, 120, 150 degrees for six polariser filters, respectively.

FIG. 14 may be used to acquire polarisation image data instead of hyperspectral image data. The data processing steps above can equally be applied to the polarisation image data, which also means that depth data can equally be determined.

It will be appreciated by persons skilled in the art that numerous variations and/or modifications may be made to the specific embodiments without departing from the scope as defined in the claims.

It should be understood that the techniques of the present disclosure might be implemented using a variety of technologies. For example, the methods described herein may be implemented by a series of computer executable instructions residing on a suitable computer readable medium. Suitable computer readable media may include volatile (e.g. RAM) and/or non-volatile (e.g. ROM, disk) memory, carrier waves and transmission media. Exemplary carrier waves may take the form of electrical, electromagnetic or optical signals conveying digital data steams along a local network or a publically accessible network such as the internet.

It should also be understood that, unless specifically stated otherwise as apparent from the following discussion, it is appreciated that throughout the description, discussions utilizing terms such as “estimating” or “processing” or “computing” or “calculating”, “optimizing” or “determining” or “displaying” or “maximising” or the like, refer to the action and processes of a computer system, or similar electronic computing device, that processes and transforms data represented as physical (electronic) quantities within the computer system's registers and memories into other data similarly represented as physical quantities within the computer system memories or registers or other such information storage, transmission or display devices.

The present embodiments are, therefore, to be considered in all respects as illustrative and not restrictive.

1. A sensor for acquiring image data, the sensor comprising:
multiple imaging elements, each of the multiple imaging elements being configured to generate an intensity signal indicative of an amount of light incident on that imaging element; and
an array of multiple lenses, each of the multiple lenses being associated with more than one of the multiple imaging elements and each of the multiple lenses of the array being associated with exactly one filter such that the intensity signals generated by the more than one of the multiple imaging elements associated with that lens represent a part of the image data.

2. The sensor of claim 1, further comprising a focusing element in front of the array of multiple lenses.

3. The sensor of claim 2, wherein the focusing element is configured such that when the sensor captures an image of a scene each of the multiple lenses projects the scene onto the multiple imaging elements associated with that lens.

4. The sensor of claim 1, further comprising a processor to determine multispectral image data based on the intensity signals, the multispectral image data comprising for each of multiple pixels of an output image wavelength indexed image data.

5. The sensor of claim 1, further comprising a processor to determine depth data indicative of a distance of an object from the sensor based on the intensity signals.

6. The sensor of claim 5, wherein the more than one imaging elements associated with each of the multiple lenses create an image associated with that lens and the processor is to determine the depth data based on spatial disparities between images associated with different lenses.

7. The sensor of claim 1, wherein all the intensity signals representing a part of the hyperspectral image data are created by exactly one filter and exactly one of the multiple lenses.

8. The sensor of claim 1, wherein the exactly one filter associated with each of the multiple lenses of the array is a single integrated filter for all of the multiple lenses and the filter has a response that is variable across the filter.

9. The sensor of claim 1, wherein the filter is a colour filter and the part of the image data is a spectral band of hyperspectral image data.

10. The sensor of claim 1, wherein the filter is a polariser and the part of the image data is a part that is polarised in a direction of the polariser.

11. A method for acquiring image data, the method comprising:
directing light reflected from a scene onto an array of multiple lenses;
directing light transmitted through each of the multiple lenses through exactly one filter;
and detecting the light transmitted through each of the multiple lenses and the exactly one filter with more than one of multiple imaging elements.

12. A method for determining image data, the method comprising:
receiving intensity signals from multiple sets of imaging elements, each set of imaging elements being associated with exactly one of multiple lenses and exactly one filter to represent a part of the image data; and
determining based on the intensity signals the image data.

13. Software that, when installed on a computer, causes the computer to perform the method of claim 12.

14. (canceled)
